(19) United States
(12) Patent Application Publication
(10) Pub. No.: US 2025/0393204 A1
(43) Pub. Date: Dec. 25, 2025

(54) NON-VOLATILE MEMORY CIRCUIT AND METHOD FOR MANUFACTURING SUCH A MEMORY CIRCUIT

(71) Applicant: STMicroelectronics International N.V., Geneva (CH)

(72) Inventors: Christian RIVERO, Peynier (FR); Julien DELALLEAU, Rousset (FR)

(73) Assignee: STMicroelectronics International N.V., Geneva (CH)

(21) Appl. No.: 19/240,601

(22) Filed: Jun. 17, 2025

(30) Foreign Application Priority Data
Jun. 19, 2024 (FR) FR2406569

(51) Int. Cl. H10B 41/35

(52) U.S. Cl. CPC H10B 41/35

(57) ABSTRACT

A non-volatile memory circuit includes a matrix of memory cells. Each memory cell includes a state transistor having a control gate and a floating gate. The state transistor is selected by a vertical selection transistor buried in a substrate and including a buried selection gate. The buried selection gate is common between the selection transistors of one and the same pair of memory cells. The buried selection gate is formed in one and the same selection gate region. The buried selection gate region has a surface indentation between each pair of twin memory cells. The surface indentation reduces a coupling by tunnel effect between the floating gates of the state transistors and the selection gate region.

### PRIORITY CLAIM

This application claims the priority benefit of French Application for Patent No. FR2406569, filed on Jun. 19, 2024, the content of which is hereby incorporated by reference in its entirety to the maximum extent allowable by law.

### TECHNICAL FIELD

Embodiments and implementations relate to non-volatile memories with charge storage.

### BACKGROUND

The reference La Rosa, et al., “40 nm embedded Select in Trench Memory (eSTM) Technology Overview”, IEEE 11th International Memory Workshop (IMW) (2019); DOI: 10.1109/IMW.2019.8739731 (incorporated by reference), describes a non-volatile memory with charge storage. This circuit uses floating gates for holding charges for storing information.

In particular, this circuit includes a matrix of memory cells having two rows and N columns. Each column of memory cells includes a pair of twin memory cells. Each memory cell comprises a selection transistor and a state transistor. The state transistor has a control gate and a floating gate. The floating gate of a state transistor can be selected by the selection transistor. The selection transistor extends vertically in the substrate. In particular, this selection transistor comprises a buried selection gate. This selection gate is common between the two selection transistors of one and the same pair of twin memory cells.

The various pairs of twin memory cells are separated from each other by shallow isolation trenches (commonly referred to in the art as shallow trench isolation (STI) structures). The common selection gates associated with the various pairs of twin memory cells are formed in one of the same selection gate region passing through said shallow isolation trenches. This selection gate region then makes it possible to define a wordline.

Thus, the selection gate region has zones located between two twin memory cells of one and the same pair and zones located between the pairs of twin memory cells in the shallow isolation trench.

The zones located between two pairs of twin memory cells can be wider than the zones located between two twin memory cells of one and the same pair. This widening brings the selection gate regions of the floating gates of the various adjacent memory cells closer together.

This proximity may cause coupling by tunnel effect between these floating gates and the selection gate region. This coupling may cause discharge of the information stored by the floating gate of a memory cell when the memory cell is accessed in read mode. The information stored in a memory cell may thus become erroneous after having been read a certain number of times. In order to correct information stored in the memory cell, error correction codes can be used, but the implementation thereof is complex and expensive in terms of computing resources.

In order to reduce coupling by tunnel effect to improve the reliability of the memory circuit, it is possible to separate the state transistors of the gate region. Nevertheless, this solution causes an increase in the planar surface required for the memory circuit.

There is therefore a need to propose a solution for reducing coupling between the floating gates and the selection gate region, without increasing the dimensions of the memory circuit.

### SUMMARY

According to one aspect, a non-volatile memory circuit is proposed comprising a matrix of memory cells including at least two rows and N columns, each memory cell comprising: a state transistor having a control gate and a floating gate, able to be selected by a vertical selection transistor buried in a substrate and including a buried selection gate; each column of memory cells including a pair of twin memory cells, the buried selection gate being common between the selection transistors of one and the same pair of memory cells, the selection gates being disposed in one and the same selection gate region; and wherein the selection gate region has a surface indentation between each pair of twin memory cells.

Advantageously, the buried selection gate only extends in the substrate.

Advantageously, the indentation is configured to reduce a coupling by tunnel effect between the floating gates of the state transistors and the selection gate region.

The indentation makes it possible to distance the gate regions of the floating gates between two pairs of memory cells. Thus, the indentation makes it possible to reduce the coupling between the selection gate region and the floating gates between two pairs of memory cells. Such a memory circuit improves the storage of data by reducing the risks of data losses. Furthermore, such an indentation makes it possible to avoid increasing the dimensions of the memory circuit.

Advantageously, the indentation has a depth of between 10 nanometers and 200 nanometers.

In an advantageous embodiment, the selection gate region is covered by a layer of oxide.

Advantageously, the memory circuit furthermore comprises spacing dielectric regions against lateral faces of the state transistors of the memory cells, the spacing dielectric regions extending partly in said indentation.

According to another aspect, a microcontroller is proposed, comprising a non-volatile memory circuit as described previously.

According to another aspect, a method is proposed for manufacturing a non-volatile memory circuit comprising: forming a matrix of memory cells including at least two rows and N columns, each memory cell comprising: a state transistor having a control gate and a floating gate, able to be selected by a vertical selection transistor buried in a substrate and including a buried selection gate, each column of memory cells including a pair of twin memory cells, the buried selection gate being common between the selection transistors of one and the same pair of memory cells, the selection gates being disposed in one and the same selection gate region; and forming an indentation on the surface of the selection gate region between each pair of twin memory cells.

Advantageously, the indentation is configured to reduce a coupling by tunnel effect between the floating gates of the state transistors and the selection gate region.

Preferably, the formation of said indentation comprises: forming a mask having openings above the selection gate region between each pair of twin memory cells; and etching the zones of the selection gate region facing said openings of the mask to form each indentation.

Such a manufacturing method is simple and inexpensive to implement. In particular, forming the indentations simply requires using an additional mask and then etching the zones located facing the openings of the mask.

### BRIEF DESCRIPTION OF THE DRAWINGS

Other advantages and features of the invention will become apparent upon examining the detailed description of embodiments, which are in no way limiting, and from the appended drawings in which:

FIG. 1 is a circuit diagram for a memory circuit;

FIG. 2 illustrates a cross section of an integrated circuit including two twin cells of the memory circuit;

FIG. 3 illustrates a cross-section between two pairs of memory cells in the integrated circuit;

FIG. 4 illustrates a plan view of a portion of the memory circuit;

FIG. 5 illustrates a three-dimensional view of a portion of a memory circuit;

FIG. 6 is a flow diagram for a method for manufacturing a memory circuit;

FIG. 7 illustrates in a three-dimensional view a result obtained in the method after having implemented the manufacture of the pairs of twin memory cells;

FIG. 8 illustrates the result obtained in the method after the deposition of the mask;

FIG. 9 illustrates a plan view of the result of the etching step in the method; and

FIG. 10 illustrates a plan view of the result of the removal of the mask in the method.

### DETAILED DESCRIPTION

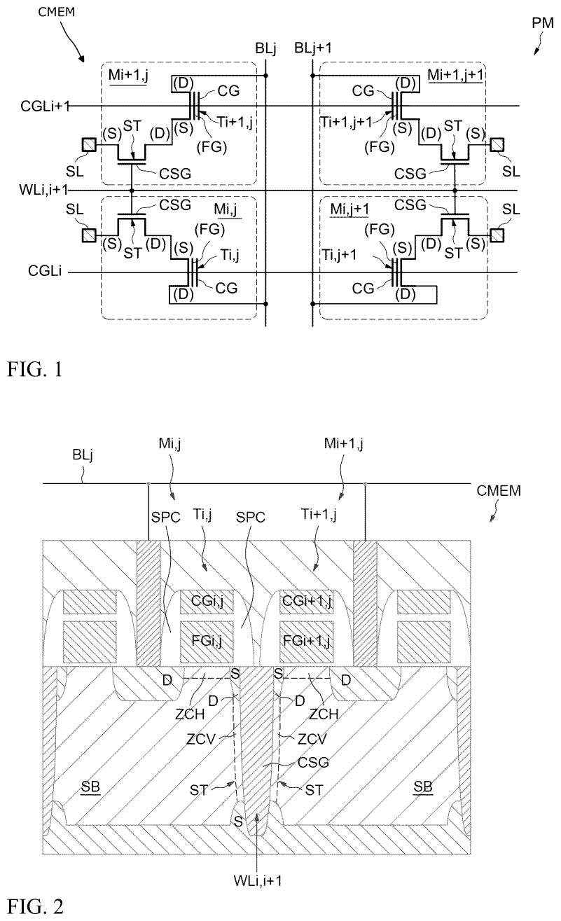

FIG. 1 illustrates a memory circuit CMEM as a circuit schematic. The memory circuit CMEM includes non-volatile memory cells. The memory circuit CMEM can be included in a microcontroller for example.

In FIG. 1, for purposes of illustration, only four memory cells Mi,j; Mi,j+1, Mi+1,j; Mi+1,j+1 are shown.

The memory cells Mi,j and Mi,j+1 of rank “i” belong to the line or row of rank i of the memory circuit and are connected to a wordline WLi,i+1 and to a gate control line CGLi.

The memory cells Mi+1,j and Mi+1,j+1 of rank “i+1” belong to the line or row of rank “i+1” of the memory circuit and are connected to the wordline WLi,i+1 and to a gate control line CGLi+1.

The memory cells Mi,j and Mi+1,j of rank “j” belonging to the column j are accessible in read and write mode by means of a single bit line BLj, and the memory cells Mi,j+1 and Mi+1,j+1 of rank “j+1” are accessible in read and write mode by means of a single bit line Blj+1.

Each memory cell M comprises a state transistor T (Ti,j; Ti,j+1, Ti+1,j; Ti+1,j+1) and a selection transistor ST. The state transistor T is configured to store information. The selection transistor ST is configured to select the state transistor T to read or write information in the state transistor T.

In particular, the state transistor T includes a floating gate (FG) surmounted by a control gate CG connected to a gate control line CGL. The floating gate makes it possible to store information.

The drain (D) of the state transistor T is connected to a bit line BL while the source(S) of the state transistor T is connected to a drain of the selection transistor ST. In particular, the drain regions (D) of the transistors Ti,j and Ti+1,j are connected to the line BLj and the drain terminals of the transistors Ti,j+1 and Ti+1,j+1 are connected to the bit line BLj+1. The control gates CG of the transistors Ti,j and Ti,j+1 are connected to the gate control line CGLi and the control gates CG of the floating gate transistors Ti+1,j and Ti+1,j+1 are connected to the gate control line CGLi+1.

The selection transistor ST includes a source (S) connected to a source line SL. Thus, each state transistor T is connected to a source line SL through the selection transistor ST.

The selection transistors ST of the memory cells Mi,j and Mi+1,j have a common selection gate CSG and the two memory cells are thereby said to be “twins”. Likewise, memory cells Mi,j+1 and Mi+1,j+1 are twin memory cells and their selection transistors ST have a common selection gate CSG.

Each selection gate CSG is a vertical gate buried in a substrate in which the memory circuit PM is produced, the source line SL also being buried. These common selection gates CSG of twin memory cells are connected to the wordline WLi,i+1.

FIG. 2 illustrates more precisely two twin cells Mi,j and Mi+1,j belonging to the same column j and to the two lines i and i+1. The two twin cells Mi,j and Mi+1,j belong to one and the same pair of twin cells. FIG. 2 is a view in cross section of the integrated circuit implementation of this pair of twin cells.

Each state transistor has a channel ZCH between its drain D and its source S. Their drain D is connected to the same bit line BLj, which is the only bit line for the column j.

The channel ZCH of the state transistor is advantageously a surface channel so that it can be possible to be able to block the conduction of the channel by applying an acceptable control voltage on the control gate of the state transistor.

Each state transistor T cooperates with a vertical selection transistor ST buried in the substrate SB.

The selection transistors ST connected to the two state transistors Ti,j and Ti+1,j each have a vertical channel ZCV and a buried vertical common selection gate CSG. It should be noted that, for purposes of simplifications of the figure, the contact for connecting the buried common selection gate CSG to the corresponding word line WLi,i+1 is not shown.

The vertical channel ZCV of each selection transistor ST extends between a drain D1, formed in the same region as the source of the state transistor of the same memory cell, and a source S1 formed in a buried diffusion region.

Each memory cell has a first state, for example an erased state, in which it stores a bit having a first logic value, for example the logic 1 value, and a second state, for example a programmed state, in which it stores a bit having a second logic value, for example the logic 0 value.

The state transistor of a memory cell is advantageously configured to be on when the memory cell is in its first state and to be off when the memory cell is in its second state.

The buried common selection gates CSG of the twin memory cells of one and the same wordline are formed in one and the same selection gate region RSG. This selection gate region RSG therefore extends longitudinally between each twin memory cell of one and the same pair and between each pair of twin memory cells. In particular, the selection gate region RSG extends between the pairs of twin memory cells in shallow isolation trenches using a Shallow Trench Isolation (STI) structure.

This selection gate region RSG has a thickness that varies over the length thereof. The thickness of the selection gate region RSG corresponds to the vertical distance between an end on the surface of the selection gate region and a buried end of the selection gate region.

FIG. 2 also illustrates spacing dielectric regions SPC disposed against the lateral faces of the gate control lines of the state transistors.

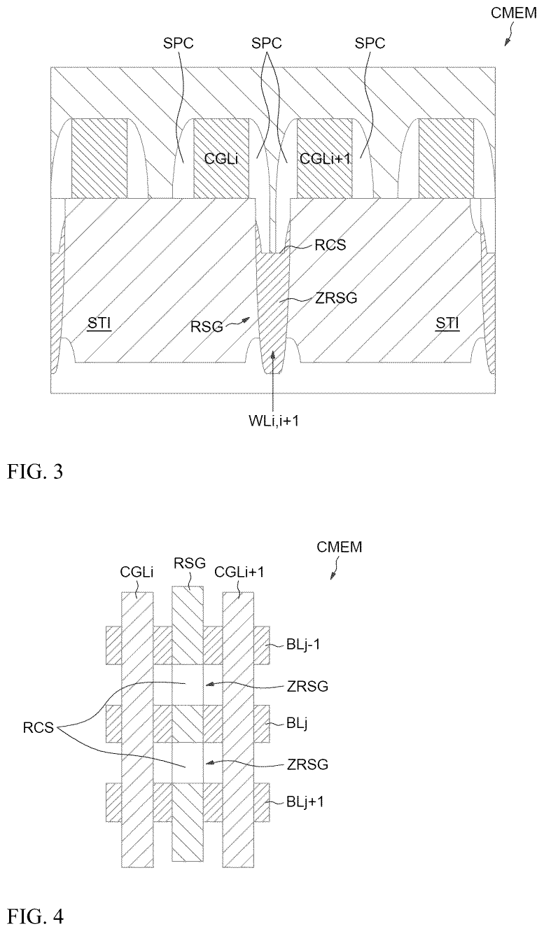

In particular, as illustrated in FIG. 3, which shows a cross-section between two pairs of memory cells, the gate region has zones ZRSG of reduced thickness from the surface end between each pair of twin memory cells in the zone of the shallow isolation trenches STI. In particular, the reduced-thickness zones ZRSG are hollowed out from the surface end. These zones ZRSG therefore each have an indentation RCS. This makes it possible to distance the selection gate region between two pairs of twin memory cells from the floating gates of these twin memory cells. Thus, the indentation RCS makes it possible to reduce the coupling between the selection gate region and the floating gates between two pairs of memory cells. Such a memory circuit improves the storage of data by reducing the risks of data losses. Furthermore, such an indentation RCS makes it possible to avoid increasing the dimensions of the memory circuit.

More particularly, the indentation RCS has a depth of between 10 nanometers and 200 nanometers.

FIG. 4 illustrates a plan view of a portion of the memory circuit. This memory portion shows two zones ZRSG each having an indentation RCS. A first zone ZRSG is located between the bit lines BLj−1 and BLj and between the gate control lines CGLi and CGLi+1. A second zone ZRSG is located between the bit lines BLj and BLj+1 and between the gate control lines CGLi and CGLi+1. FIG. 4 does not illustrate the spacing dielectric regions SPC in order to simplify the view.

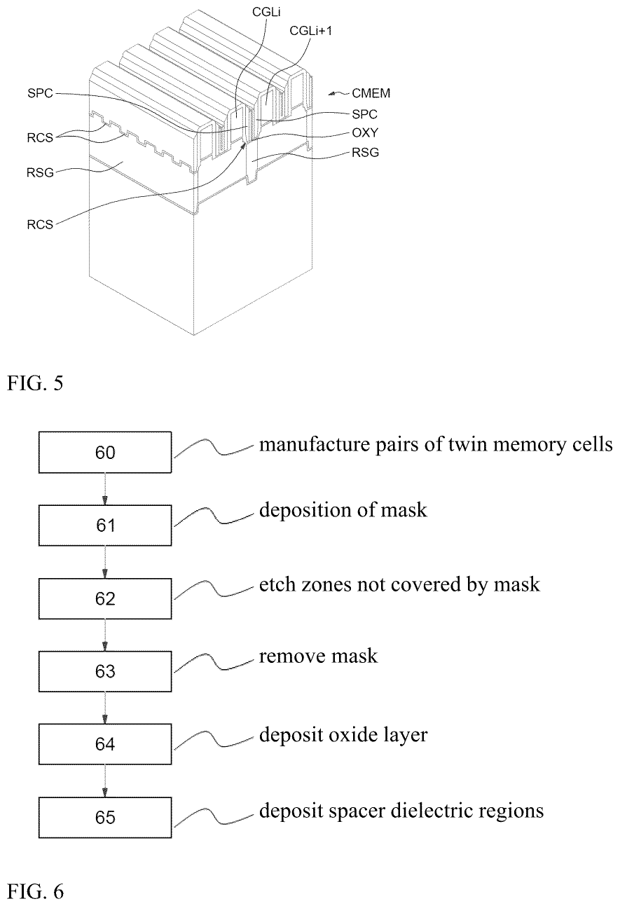

FIG. 5 illustrates a three-dimensional view of a portion of a memory circuit as described previously. This FIG. 5 shows the indentations RCS located over the length of the selection gate region SG between each pair of twin memory cells. This figure also shows the spacing dielectric regions SPC that extend against the lateral faces of the gate control lines of the state transistors and partly in said indentation RCS.

The selection gate region RSG is deposited on a first layer of oxide OXY1 and is covered by a second layer of oxide OXY also on the surface. This second layer of oxide OXY extends, in particular, in the indentations RCS of the selection gate region RSG.

FIG. 6 illustrates a flow diagram for an example embodiment of the method for manufacturing a memory circuit as described previously.

The manufacturing method comprises a manufacture 60 of pairs of twin memory cells, each twin memory cell having a state transistor and a selection transistor. The manufacture of pairs of twin memory cells is well known to persons skilled in the art. The gates CSG of the selection transistors connected to one and the same wordline WL are formed in one and the same selection gate region RSG extending in depth in the substrate. The selection gate region as at this stage widened zones ENL between the pairs of twin memory cells.

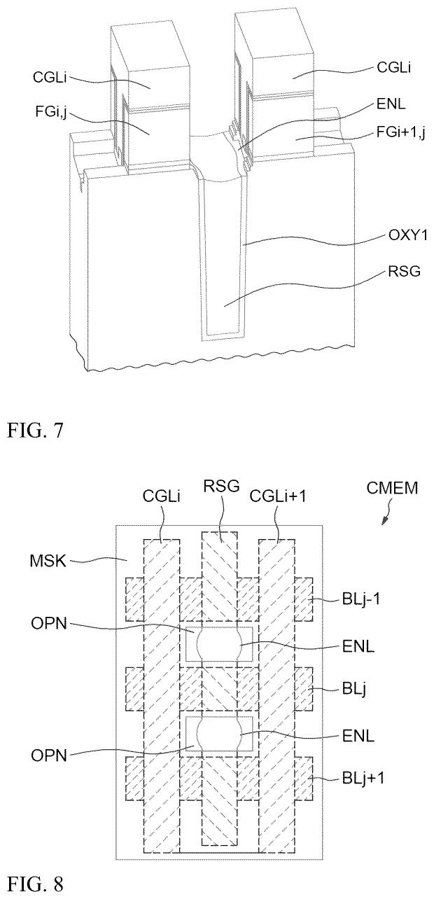

FIG. 7 illustrates a result that can be obtained after having implemented the manufacture of the pairs of twin memory cells (i.e., at the end of step 60).

The manufacturing method next comprises deposition 61 of a mask MSK. FIG. 8 illustrates the result obtained after the deposition 61 of the mask MSK. In particular, the mask MSK is configured to have openings OPN facing the zones of the selection gate region located between the pairs of twin memory cells. Thus, the mask MSK is configured to cover each pair of twin memory cells as well as on the zones of the selection gate region between the twin memory cells. The mask is also configured to cover the zones of the gate control lines CG1, CG2 located between the pairs of memory cells.

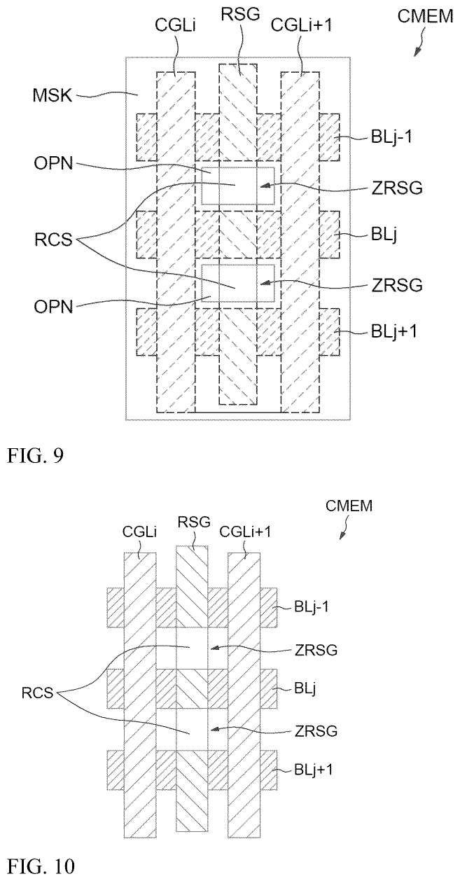

The method next comprises an etching 62 of the zones not covered by the mask, i.e. the zones ZRSG of the selection gate region CSG located between the pairs of twin memory cells facing the openings OPN of the mask MSK. Preferably, the etching 62 is a dry etching, in particular a plasma etching. FIG. 9 illustrates a plan view of an example of a result of the etching step 62.

The method next comprises a removal 63 of the mask MSK. FIG. 10 illustrates a plan view of an example of a result of the removal of the mask MSK.

The method next comprises a deposition 64 of a layer of oxide OXY on the memory cells and on the selection gate region.

The method next comprises a deposition 65 of spacing dielectric regions SPC against the lateral faces of the state transistors of the memory cells. These spacing dielectric regions SPC also extend in the indentations RCS of the selection gate region.

Such a manufacturing method is simple and inexpensive to implement. In particular, forming the indentations RSC simply requires using an additional mask MSK and then etching the zones ZRSG located facing the openings of the mask MSK.

1. A non-volatile memory circuit, comprising:
a matrix of memory cells including at least two rows and N columns;
wherein each memory cell comprises:
a state transistor having a control gate and a floating gate, said state transistor configured to be selected by a vertical selection transistor buried in a substrate and including a buried selection gate;
wherein each column of memory cells includes a pair of twin memory cells, the buried selection gate being common between the selection transistors of one and the same pair of memory cells, the buried selection gate being disposed in one and the same selection gate region; and
wherein the buried selection gate region has a surface indentation between each pair of twin memory cells.

2. The circuit according to claim 1, wherein the surface indentation is configured to reduce a coupling by tunnel effect between the floating gates of the state transistors and the selection gate region.

3. The circuit according to claim 1, wherein the surface indentation has a depth of between 10 nanometers and 200 nanometers.

4. The circuit according to claim 1, wherein the selection gate region is covered by a layer of oxide.

5. The circuit according to claim 1, further comprising spacing dielectric regions against lateral faces of the state transistors of the memory cells, the spacing dielectric regions extending partly in said surface indentation.

6. A microcontroller comprising the non-volatile memory circuit according to claim 1.

7. A method for manufacturing a non-volatile memory circuit, comprising:
forming a matrix of memory cells including at least two rows and N columns;
wherein each memory cell comprises: a state transistor having a control gate and a floating gate, said state transistor configured to be selected by a vertical selection transistor buried in a substrate and including a buried selection gate;
wherein each column of memory cells includes a pair of twin memory cells, the buried selection gate being common between the selection transistors of one and the same pair of memory cells, the buried selection gate being disposed in one and the same selection gate region; and
forming an indentation on the surface of the selection gate region between each pair of twin memory cells.

8. The method according to claim 7, wherein the indentation is configured to reduce a coupling by tunnel effect between the floating gates of the state transistors and the selection gate region.

9. The method according to claim 7, wherein forming said indentation comprises:
forming a mask having openings above the selection gate region between each pair of twin memory cells; and
etch zones of the selection gate region facing said openings of the mask to form each indentation.
